(19) United States
(12) Patent Application Publication
(10) Pub. No.: US 2004/0085115 A1
(43) Pub. Date: May 6, 2004

(54) Source-follower circuit having low-loss output statge portion and drive device for liquid-display display device

(75) Inventors: Tatsumi Fujiyoshi, Miyagi-ken (JP); Ken Kawabata, Miyagi-ken (JP)

Correspondence Address: BEYER WEAVER & THOMAS LLP, P.O. BOX 778, BERKELEY, CA, 94704-0778, US

(73) Assignee: ALPS ELECTRIC CO., LTD.

(21) Appl. No.: 10/681,058

(22) Filed: Oct. 7, 2003

(30) Foreign Application Priority Data
Nov. 6, 2002 (JP) 2002-322540
Jul. 10, 2003 (JP) 2003-195213

(51) Int. Cl. H03K 17/687

(52) U.S. Cl. 327/427

(57) ABSTRACT

When a set signal goes high, a gate-source voltage is stored by an input capacitor such that an NMOS transistor maintains a source potential at a drain current. Next, when a set signal goes low and a write signal goes high, the NMOS transistor performs a source-follower operation and enters a stable state while charging a load capacitor. At timing when writing into the load capacitor is finished, the set signal and the write signal are put into low states. By doing this, the writing voltage is stored by the load capacitor. At the same time, current sources are forcibly turned off and the flow of a very small amount of bias current completely stops so that no power is consumed.

### BACKGROUND OF THE INVENTION

1. Field of the Invention

This invention relates to low-power-consumption analog buffer circuits and drive circuit devices. More particularly, the present invention relates to a source-follower circuit used at an output stage of a source driver for a liquid-crystal display device and a drive device for a liquid-crystal display apparatus.

2. Description of the Related Art

As shown in FIG. 11, a liquid-crystal display apparatus includes scan lines 1, data lines 2, thin-film transistors 3, pixel electrodes 4, and an opposing electrode (not shown). Liquid crystal is provided between the pixel electrodes 4 and the opposing electrode. A scan driver 10 sequentially selects the scan lines 1, and a data driver 11 sends analog signals to the data lines 2.

In the data driver 11, a shift-register data latch 12 distributes a multiplexed digital signal to each channel in accordance with a timing control 9, and an R-string 13 and a digital-to-analog (D/A) converter 14 perform digital-to-analog conversion on the digital signal, which is sent to the corresponding data line 2 via the buffer 15. The buffer 15 is required to promptly drive the data line 2 having a capacitive load, and a circuit having an operation amplifier shown in FIG. 12 is commonly used (e.g., Japanese Unexamined Patent Application Publication No. 2000-338461).

Meanwhile, referring to FIG. 12, an operational amplifier P3 used at the output stage requires bias currents I₁ and I₂ to maintain its operation. In particular, the bias current I₂ must be large to drive the load. For example, when writing is performed on a condition that a load Cload is 30 pF, an output voltage Vout is 5V, and time t is 5 μsec, at least the bias current I₂ needs to satisfy the equation: I₂=Cload×Vout/t=30 μA.

However, conventionally, even when the output voltage Vout is lower than or equal to 5 V, the bias current I₂ is caused to flow even after the completion of writing. Thus, when such a circuit is used to drive a QVGA (quarter video graphics array) panel (320×RGB), a power of I₂×320×3×5=144 mW is consumed by only the output stage of the operation amplifier P3.

Essentially, when a power required for charging and discharging electricity of the load is simply estimated, the following equation is given:

I/2fCV²=½×(60 Hz×240)×(30 pF×320×3)×(5V)²=5.2 mW

In practice, although measures for reducing power, such as cutting off bias current after the completion of writing, have been taken, such measures are not sufficient and most power has been consumed as a loss in the operational amplifier. That is, when a liquid-crystal display device is used as a portable terminal, it needs to consume less power and thus the power consumption of the buffer 15 is a major problem.

### SUMMARY OF THE INVENTION

The present invention has been made in view of the foregoing situations, and an object of the present invention is to provide a source-follower circuit and drive device for a liquid-crystal display device, which can considerably reduce the loss of an output stage portion and can reduce the power consumption of a data driver and also the entire liquid-crystal display device.

To overcome the foregoing problem, according to a first aspect of the present invention, there is provided a source-follower circuit for driving a load at an input voltage for the circuit. The source-follower circuit includes a MOS transistor; capacitance portion for storing a gate potential of the MOS transistor; and bias-current supplying portion, which includes a source-side current source and a drain-side current source, for supplying a bias current to the MOS transistor. The source-follower circuit further includes control portion for forcibly setting a source potential of the MOS transistor to the input voltage so that the MOS transistor's gate potential that is varied by the bias-current supplying portion is stored by the capacitance portion, and then, for applying the gate potential stored by the capacitance portion to a gate of the MOS transistor so that the MOS transistor is operated and the source-side current source is operated, thereby driving the load at the input voltage.

The MOS transistor may include an NMOS transistor and a PMOS transistor. The control portion selectively drives one of the NMOS transistor and the PMOS transistor in accordance with the value of the input voltage.

One end of the capacitance portion may be connected to ground or a constant potential.

To overcome the above-described problem, according to another aspect of the present invention, there is provided a source-follower circuit for driving a load at an input voltage for the circuit. The source-follower circuit includes a first MOS transistor; first capacitance portion for storing a gate potential of the first MOS transistor; first bias-current supplying portion, which includes a source-side current source and a drain-side current source, for supplying bias current to the first MOS transistor; a second MOS transistor; second capacitance portion for storing a gate potential of the second MOS transistor; and second bias-current supplying portion, which includes a drain-side current source, for supplying bias current to the second MOS transistor. The source-follower circuit further includes control portion for forcibly setting a source potential of the first MOS transistor to the input voltage so that the first MOS transistor's gate potential that is varied by the first bias-current supplying portion is stored by the first capacitance portion, for causing the second capacitance portion to store a difference potential between a gate voltage of the second MOS transistor and the input voltage, the gate voltage of the second MOS transistor being generated by the second bias-current supplying portion, and then, for applying the gate potential stored by the first capacitance portion to a gate of the first MOS transistor so that the first MOS transistor is operated and applying the difference potential, stored by the second capacitance portion, between an output terminal for the load and a gate of the second MOS transistor so that the second MOS transistor is operated, thereby driving the load at the input voltage.

The source-follower circuit may further include a first circuit having the first MOS transistor and the second MOS transistor, both thereof being NMOS transistors, and a second circuit having the first MOS transistor and the second MOS transistor, both thereof being PMOS transistors. The control portion selectively drives one of the first circuit and the second circuit in accordance with the value of the input voltage.

The source-follower circuit may further include resistance control portion. The second MOS transistor is constituted by third and fourth MOS transistors, and sources and gates of the third and fourth MOS transistors are interconnected. The resistance control portion controls an inter-drain resistor provided between drains of the third and fourth MOS transistors when a difference potential between a gate voltage of the third and fourth MOS transistors and the input voltage is stored by the second capacitance portion and when the difference potential stored by the second capacitance portion is applied between the output terminal for the load and the gates of the third and fourth MOS transistors.

The inter-drain resistor may be constituted by fifth, sixth, and seventh MOS transistors. The resistance control portion controls each transistor to be turned on and off so that a resistance value is adjusted.

To overcome the above-described problem, according to another aspect of the present invention, there is provided a drive device for a liquid-crystal display device. The liquid-crystal display device has a scan line and a data line which are connected so as to cross each other via a thin film transistor connected to a pixel electrode and the drive device has a data driver for supplying an analog signal to the data line. The data driver has a buffer circuit that includes a MOS transistor; capacitance portion for storing a gate potential of the MOS transistor; bias-current supplying portion, which includes a source-side current source and a drain-side current source, for supplying bias current to the MOS transistor. The buffer circuit further includes control portion for forcibly setting a source potential of the MOS transistor to the input voltage so that the MOS transistor's gate potential that is varied by the bias-current supplying portion is stored by the capacitance portion, and then, for applying the gate potential stored by the capacitance portion to a gate of the MOS transistor so that the MOS transistor is operated and the source-side current source is operated, thereby driving the load at the input voltage.

The MOS transistor may include an NMOS transistor and a PMOS transistor. The control portion selectively drives one of the NMOS transistor and the PMOS transistor in accordance with the value of the input voltage.

One end of the capacitance portion may be connected to ground or a constant potential.

To overcome the above-described problem, according to still another aspect of the present invention, there is provided a drive device for a liquid-crystal display device. The liquid-crystal display device has a scan line and a data line which are connected so as to cross each other via a thin film transistor connected to a pixel electrode and the drive device has a data driver for supplying an analog signal to the data line. The data driver has a buffer circuit that includes a first MOS transistor; first capacitance portion for storing a gate-source bias voltage of the first MOS transistor; first bias-current supplying portion, which includes a source-side current source and a drain-side current source, for supplying bias current to the first MOS transistor; a second MOS transistor; second capacitance portion for storing a gate potential of the second MOS transistor; and second bias-current supplying portion, which includes a drain-side current source, for supplying bias current to the second MOS transistor. The buffer circuit further includes control portion for forcibly setting a source potential of the first-MOS transistor to the input voltage so that a first MOS transistor's gate potential that is varied by the first bias-current supplying portion is stored by the first capacitance portion, for causing the second capacitance portion to store a difference potential between a gate voltage of the second MOS transistor and the input voltage, the gate voltage of the second MOS transistor being generated by the second bias-current supplying portion, and then, for applying the gate potential stored by the first capacitance portion to a gate of the first MOS transistor so that the first MOS transistor is operated and applying the difference potential, stored by the second capacitance portion, between an output terminal for the load and a gate of the second MOS transistor so that the second MOS transistor is operated, thereby driving the load at the input voltage.

The data driver may further include a first circuit having the first MOS transistor and the second MOS transistor, both thereof being NMOS transistors, and a second circuit having the first MOS transistor and the second MOS transistor, both thereof being PMOS transistors. The control portion selectively drives one of the first circuit and the second circuit in accordance with the value of the input voltage.

The drive device may further include resistance control portion. The second MOS transistor may be constituted by third and fourth MOS transistors, and sources and gates of the third and fourth MOS transistors are interconnected. The resistance control portion controls a resistance value of an inter-drain resistor provided between drains of the third and fourth MOS transistors when a difference potential between a gate voltage of the third and fourth MOS transistors and the input voltage is stored by the second capacitance portion and when the difference potential stored by the second capacitance portion is applied between the output terminal for the load and the gates of the third and fourth MOS transistors.

The inter-drain resistor may be constituted by fifth, sixth, and seventh MOS transistors. The resistance control portion controls each transistor to be turned on and off so that a resistance value is adjusted.

According to the present invention, the control portion forcibly sets a source potential of the MOS transistor to the input voltage so that the MOS transistor's gate potential that is varied by the bias-current supplying portion is stored by the capacitance portion, and then applies the gate potential stored by the capacitance portion to the gate of the MOS transistor so that the MOS transistor is operated and the source-side current'source is operated, thereby driving the load at the input voltage. Thus, the present invention provides advantages in that the loss at the output stage portion can be significantly reduced and the power consumptions of data driver and the entire liquid-crystal display device can be reduced.

### BRIEF DESCRIPTION OF THE DRAWINGS

FIG. 1 is an equivalent circuit diagram illustrating the configuration of an analog buffer circuit according to a first embodiment of the present invention;

FIG. 2 is a timing chart for describing the operation of the analog buffer circuit of the first embodiment;

FIG. 3 is an equivalent circuit diagram illustrating the configuration of an analog buffer circuit according to a second embodiment of the present invention;

FIG. 4 is a timing chart for describing the operation of the analog buffer circuit of the second embodiment;

FIG. 5 is an equivalent circuit diagram illustrating the configuration of an analog buffer circuit according to a third embodiment of the present invention;

FIG. 6 is an equivalent circuit diagram illustrating the configuration of an analog buffer circuit according to a fourth embodiment of the present invention;

FIG. 7 is an equivalent circuit diagram illustrating the configuration of an analog buffer circuit according to a fifth embodiment of the present invention;

FIGS. 8A and 8B are equivalent circuit diagrams for describing the configuration of an analog buffer circuit according to a sixth embodiment of the present invention;

FIG. 9 is a graph for describing the operation of the analog buffer circuit of the sixth embodiment;

FIG. 10 is a graph for describing an effect of the analog buffer circuit of the sixth embodiment;

FIG. 11 is a block diagram illustrating the configuration of a known liquid-crystal display device; and

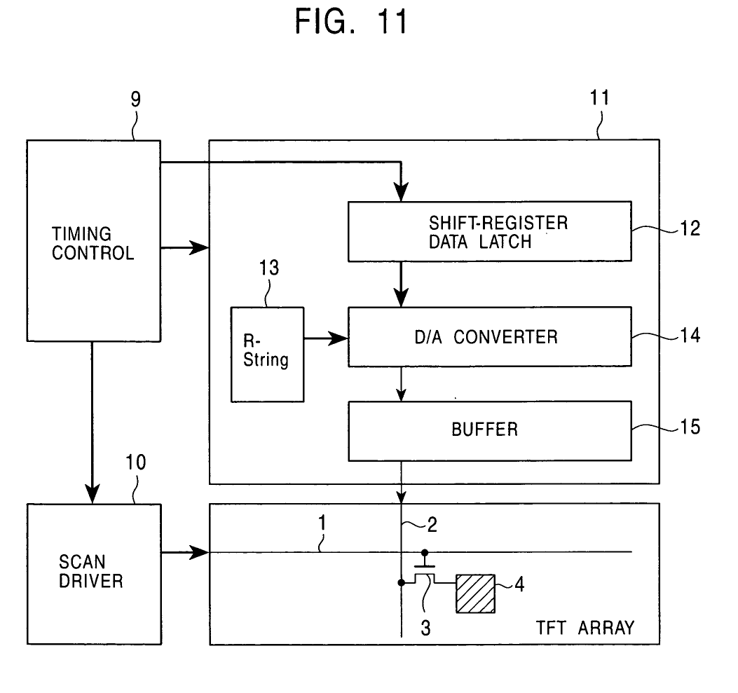

FIG. 12 is an equivalent circuit diagram illustrating the circuit configuration of a buffer in a know liquid-crystal display device.

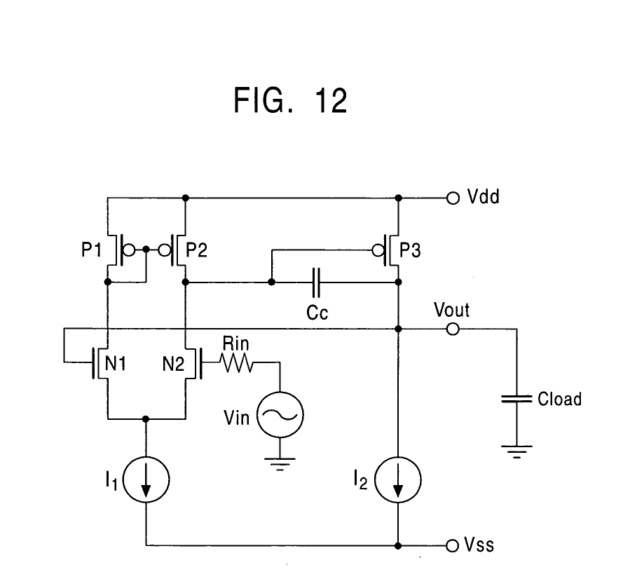

### DESCRIPTION OF THE PREFERRED EMBODIMENTS

Embodiments of the present invention will be described below with reference to the accompanying drawings.

### First Embodiment

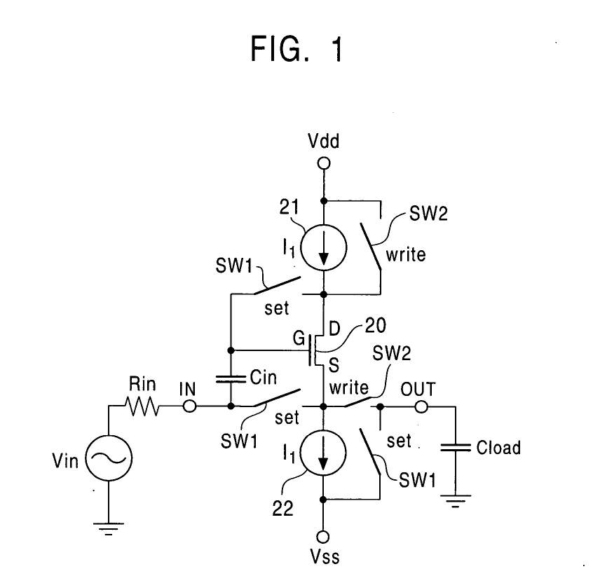

FIG. 1 is an equivalent circuit diagram illustrating the configuration of an analog buffer circuit according to a first embodiment of the present invention. Referring to FIG. 1, current sources 21 and 22, which supply the same current, are connected to the drain D and the source S of an n-channel metal oxide semiconductor transistor 20 (hereinafter referred to as an “NMOS transistor”), respectively. An input capacitor Cin is connected between the gate G of the NMOS transistor 20 and an input. Analog switches SW1, which close in response to a set signal, and analog switches SW2, which close in response to a write signal, are connected to the circuit, as shown. In operation, this circuit is put into three states, namely, a pre-charge period, a write period, and a hold period.

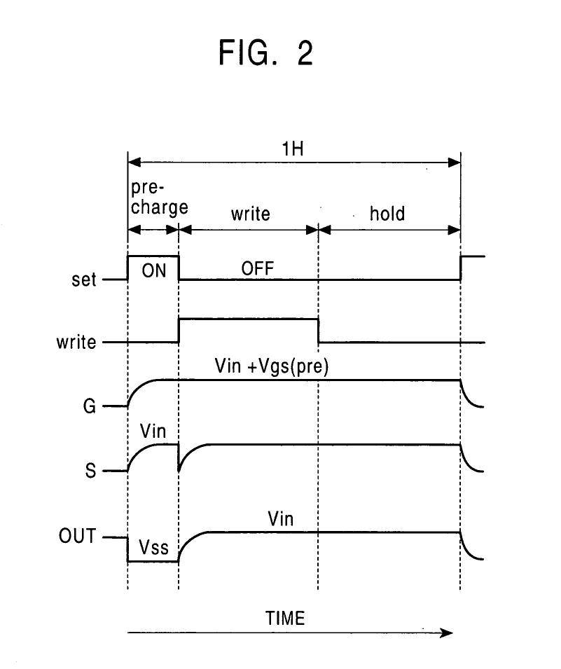

FIG. 2 is a timing chart for describing the operation of the analog buffer circuit of the first embodiment.

### (a) Pre-Charge Period

When the set signal goes high, the analog switch SW1 is turned on so that drain current I₁ flows from the current source 21 to the NMOS transistor 20. A gate-source voltage Vgs is automatically biased so as to correspond to the drain current I₁. Also, the source potential is set to the value of a source potential Vin, but no current flows into the source node from the source potential Vin because of the relationship of the input and output current of the source node. Thus, a sufficiently large value is ensured for the input impedance.

In this manner, the gate-source voltage Vgs (pre) is stored by the input capacitor Cin such that the NMOS transistor 20 maintains the source potential Vin at the drain current I₁. At this point, the gate potential becomes Vin+Vgs (pre). On the other hand, a load Cload is discharged to Vss.

### (b) Write Period

When the set signal goes low and the write signal goes high, the analog switch SW1 is turned off and the analog switch SW2 is turned on. While the gate potential is still at Vin+Vgs (pre), the NMOS transistor 20 performs a source-follower operation and the source potential becomes Vin and the drain current I₁ enters a stable state, while charging the load capacitor Cload. When the drain current I₁ is too small, the NMOS transistor 20 operates on the verge of being cut off, and when the source potential comes close to Vin, the driving capability sharply decreases. Setting the drain current I₁ to about 1 μA allows charging at 30 pF within 4 μsec.

### (c) Hold Period

At timing when the writing into the load capacitor is finished, when the set signal and the write signal are both put into the low states, the analog switches SW1 and SW2 are turned off. Thus, the write voltage is held in the load capacitor. At the same time, the two current sources 21 and 22 are forcibly turned off. As a result, even the flow of a very small amount of bias current I₁ completely stops, so that no power is consumed.

According to the operation described above, the power consumption of the buffer portion can be reduced to about 17 mW. For the above operation, although the NMOS transistor 20 has been used, a PMOS (p-channel metal oxide semiconductor) transistor may also be used with the circuit configured to be symmetric.

### Second Embodiment

A second embodiment of the present invention will now be described. In the first embodiment described above, the output voltage OUT is operated only to a level of about 1 V lower than Vdd, in order to maintain the voltage drop in the current source 21 and 22 and the operation region of the NMOS transistor 20 in the saturation region. In the case of a PMOS transistor, conversely, the output voltage OUT is operated down to a level of about 1 V higher than Vss. The second embodiment overcomes this problem.

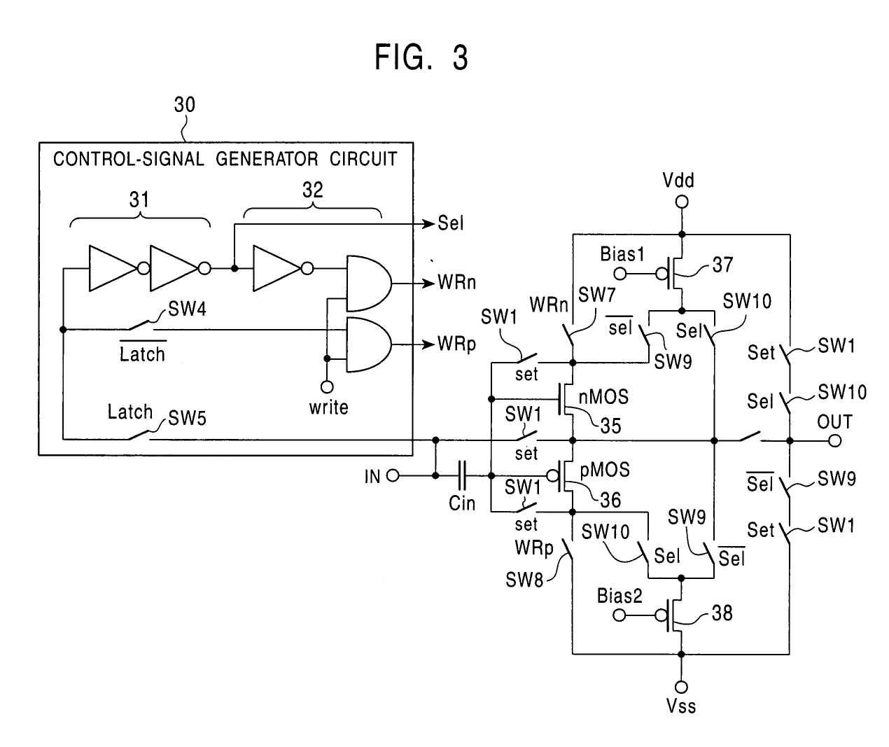

FIG. 3 is an equivalent circuit diagram illustrating the configuration of an analog buffer circuit according to a second embodiment of the present invention. A control-signal generator circuit 30 includes a latch circuit 31, which has two inverters, and a circuit 32 for shaping a control signal generated from the latch circuit 31. An input signal IN is divided by the latch circuit 31 at about one half the threshold (Vlt) of a power supply voltage and is latched. Therefore, when the input voltage IN is lower than the threshold voltage Vlt, a Sel (select) signal goes low and when the input voltage IN is higher than or equal to the threshold voltage Vlt, the Sel signal goes high.

A switch SW4 is turned on in response to a (negative) latch signal, and a switch SW5 is turned on in response to a latch signal. WRn indicates a control signal that is sent via an NMOS Transistor 35 to close a switch SW7 for charging during a write period, and similarly, WRp is sent via a PMOS transistor 36 to close a switch SW8. Switches SW9 are turned on in response to a (negative) Sel signal. Switches SW10 are also turned on in response to a Sel signal. A PMOS transistor 37 and an NMOS transistor 38 are used as current sources.

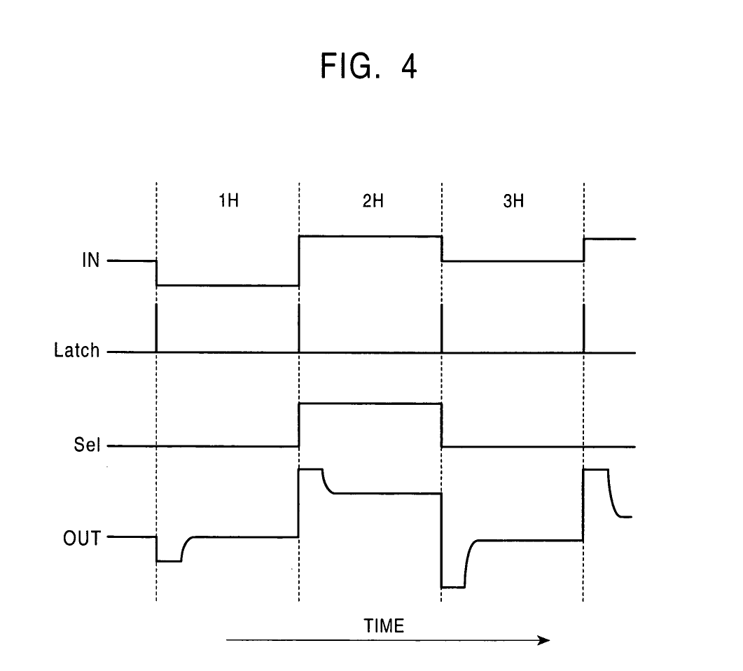

FIG. 4 is a timing chart for describing the operation of the analog buffer circuit of the second embodiment. In a 1 H period shown in FIG. 4, the input voltage IN is lower than the threshold voltage Vlt and the Sel signal goes low. Thus, in a pre-charge period, the output voltage OUT is discharged to Vss. In the next write period, the switch SW7 is closed in response to the signal WRn, and the source-follower circuit of the NMOS transistor 35 causes OUT to be charged to a desired potential.

In a 2 H period, the input voltage IN is higher than the threshold voltage Vlt and the Sel signal goes high. Thus, in the precharge period, OUT is charged at Vdd. In the next write period, the switch SW8 is closed in response to the signal WRp, and the source-follower circuit of the PMOS transistor 36 causes OUT to be discharged to reach a desired potential.

In this manner, when the input voltage IN is lower than the threshold voltage Vlt, the source-follower circuit of the NMOS transistor 35 is operated, and when the input voltage IN is higher than the threshold voltage Vlt, the source-follower circuit of the PMOS transistor 36 is operated, so that operation is possible in substantially all regions from Vss to Vdd.

### Third Embodiment

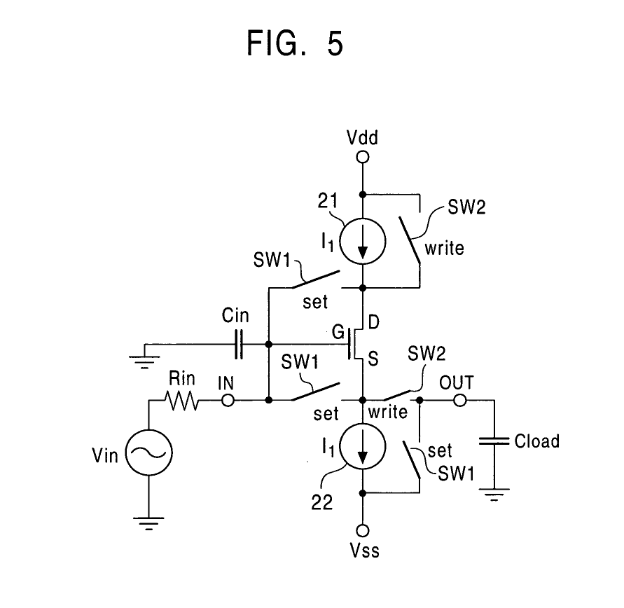

A third embodiment of the present invention will now be described. FIG. 5 is an equivalent circuit diagram illustrating the configuration of an analog buffer circuit according to a third embodiment of the present invention. Portions and elements corresponding to those in FIG. 1 are denoted with the same reference numerals, and the descriptions thereof will be omitted. One of the nodes of an input capacitor Cin is connected to ground. In a precharge period, the gate potential is at Vgs (pre)+Vin, and this voltage is held by the input capacitor Cin without being changed. Thus, even when an input voltage IN is disconnected in a write period, information of Vin is maintained and the analog buffer circuit of this embodiment performs an operation analogous to that of the first embodiment.

In general, when capacitance is formed in an IC (integrated circuit), there may be no other choice but to use one electrode for the substrate potential in order to form a stable potential, depending on a process. In such a case, the circuit configuration of the third embodiment is effective. Further, in a write period, the third embodiment allows the input voltage IN to be disconnected and also provides an advantage in that a digital-to-analog conversion process at the Vin side can be performed in parallel.

### Fourth Embodiment

A fourth embodiment of the present invention will now be described. The first to third embodiments described above require the pre-charge operation before the write operation since the range of output voltage of the source follower is limited. This means that the load may be driven to an output voltage more than originally required, thereby consuming unwanted power. The fourth embodiment overcomes this problem.

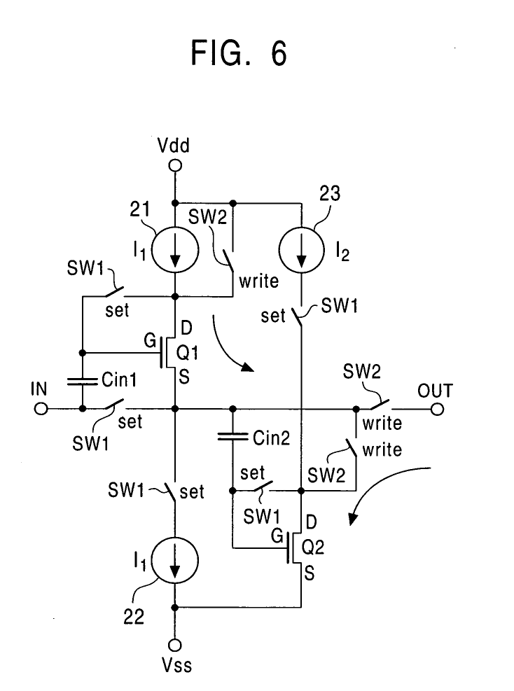

FIG. 6 is an equivalent circuit diagram illustrating the configuration of an analog buffer circuit according to a fourth embodiment of the present invention. The operation timings of the fourth embodiment are analogous to those of the first embodiment shown in FIG. 2, but the analog buffer circuit of the forth embodiment does not perform the discharge operation of the load Cload. In FIG. 6, a MOS transistor Q1 performs the same operation as that shown in FIG. 1. The MOS transistor Q1 serves to supply current to the load capacitor Cload.

Also, with regard to a MOS transistor Q2, a difference potential between a gate potential and an input potential, which is biased to a gate-source voltage Vgs so as to correspond to a current I₂, is stored by an input capacitor Cin2. Thus, during a write period, when the potential of the load capacitor Cload reaches Vin, the drain current becomes the current I₂.

In this case, suppose I₁=I₂, when the potential of the load capacitor Cload is larger than the source potential Vin, the MOS transistor Q2 draws in current until the potential of the load capacitor Cload reaches the source potential Vin and the MOS transistor Q1 is cut off. When the potential of the load capacitor Cload is smaller than the source potential Vin, the MOS transistor Q1 supplies current until the potential of the load capacitor Cload reaches the source potential Vin and the MOS transistor Q2 is cut off.

In this manner, the forth embodiment of the present invention allows a push-pull operation for the load capacitor Cload. Thus, this can eliminate the pre-charge operation, making it possible to reduce power consumption for the pre-charge operation and thus to achieve low power consumption.

### Fifth Embodiment

A fifth embodiment of the present invention will now be described. In the fourth embodiment described above, the output voltage OUT is operated only to a level of about 1 V lower than Vdd to maintain the operation region of the MOS transistor Q1 shown in FIG. 6 in the saturation region, in the same manner as that of the first embodiment. The fifth embodiment overcomes this problem.

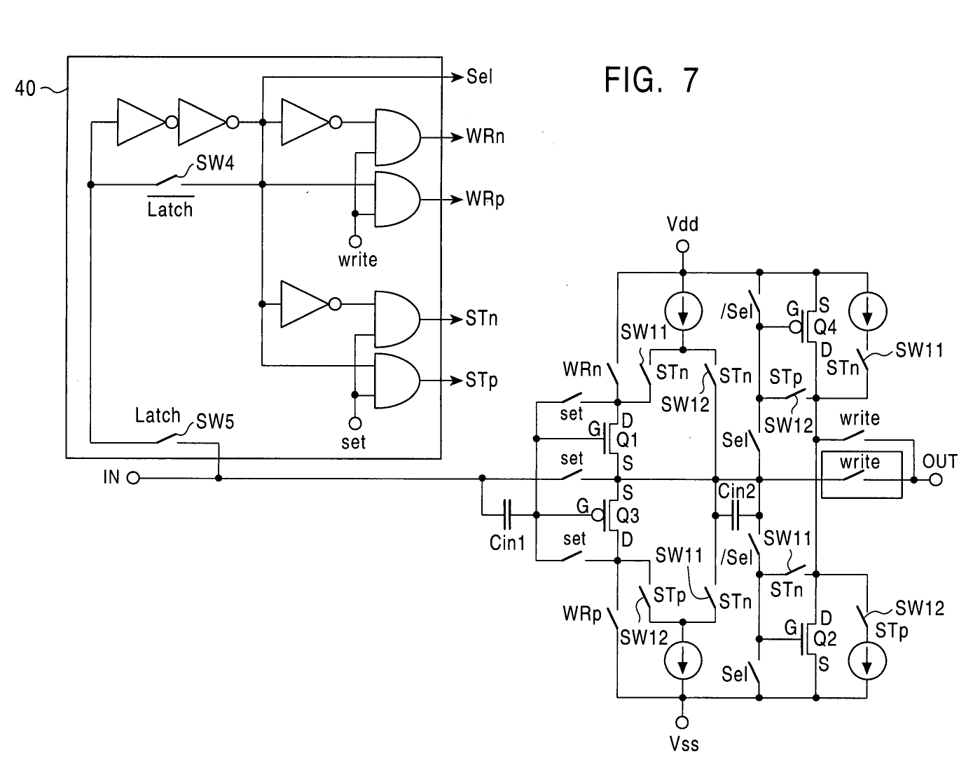

FIG. 7 is an equivalent circuit diagram illustrating the configuration of an analog buffer circuit according to a fifth embodiment of the present invention. The timing chart for description of the operation is analogous to that shown in FIG. 4. The analog buffer circuit of the fifth embodiment uses a control-signal generator circuit 40, as in the second embodiment. In the control-signal generator circuit 40, as in the second embodiment, when the input voltage IN is smaller than the threshold voltage Vlt, the Sel signal goes low, and when the input voltage IN is higher than or equal to the threshold voltage Vlt, the Sel signal goes high. In response to the Sel signal and the set signals, an STn signal and an STp signal are additionally output. Switches SW11 are turned on in response to the STn signal and switches SW12 are turned on in response to the STp signal. By using the STn and STp signals, NMOS transistors Q1 and Q2 operate when the input voltage IN is lower than the threshold voltage Vlt and PMOS transistors Q3 and Q4 operate when the input voltage IN is higher than or equal to the threshold voltage Vlt. Thus, the analog buffer circuit of this embodiment can operate in substantially all ranges from Vss to Vdd.

### Sixth Embodiment

A sixth embodiment of the present invention will now be described. In the fifth embodiment described above, when Vin becomes very close to Vss or Vdd, the operation range of the MOS transistor Q2 or the MOS transistor Q4 shifts from a saturation region to a linear region. Thus, a potential difference is generated between Vin and the output voltage OUT. The sixth embodiment is, therefore, intended to reduce the potential difference between the input voltage IN and the output voltage OUT.

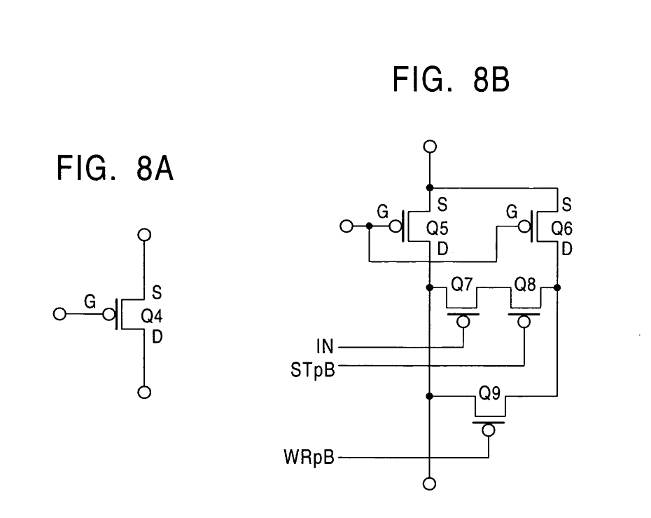

In the fifth embodiment described above, the MOS transistor Q4 shown in FIG. 7 (FIG. 8A) is constituted by a plurality of MOS transistors Q5 to Q9 as shown in FIG. 8B. Drain current Id in the saturation region of the MOS transistor can be given by the following expression (1).

$$Id = \frac{1}{2} \cdot Ko \cdot \frac{W}{L} \cdot {( Vgs - Vt )}^{2} \qquad ( 1 )$$

where K0 is a constant determined in the manufacturing process, W is the channel width of the MOS transistor, L is the channel length, Vgs is a gate-source voltage, and Vt is a threshold voltage.

Referring to FIG. 8A, when a source-drain voltage of the MOS transistor Q4 is smaller than a voltage (Vgs−Vt), the operation range shifts from the saturation region to the linear region, so that the current Id flowing between the source and the drain sharply decreases. The drain current Id in the linear region can be given by the following expression (2). Vds indicates a drain-source voltage.

$$Id = Ko \cdot \frac{W}{L} \{ ( Vgs - Vt ) \cdot Vds - \frac{1}{2} {V}^{2} ds \} \qquad ( 2 )$$

Thus, in FIG. 7, when the input voltage IN is greater than or equal to Vdd−|Vgs−Vt|, the operation range of the MOS transistor Q4 goes out of the saturation region and thus the output voltage OUT becomes smaller than the input voltage IN.

Accordingly, the MOS transistor Q4 is constituted by MOS transistors Q5 and Q6, as shown in FIG. 8B. In this case, W/L (Q4)=W/L (Q5)+W/L (Q6) is satisfied.

When the input voltage IN is sufficiently low, the MOS transistor Q7 is turned on. Further, during a pre-charge period, the MOS transistor Q8 is turned on in response to an STpB signal (an L-level signal because of negative logic), and, during a write period, the MOS transistor Q9 is turned on in response to a WRpB signal (an L-level signal because of negative logic). Consequently, the drains of the MOS transistors Q5 and Q6 are always in connected states, and thus this configuration can be regarded as one MOS transistor in which the sum of the W/L is equal to that of the MOS transistor Q4. Thus, from the expression (1), the drain current in the MOS transistor Q4 shown in FIG. 8A and the sum of the drain currents of the MOS transistors Q5 and Q6 shown in FIG. 8B are equal, so that the operations shown in FIG. 8A and FIG. 8B are substantially the same.

When the input voltage IN increases and the potential difference between Vdd and the input voltage IN is smaller than the sum of the threshold voltages of the MOS transistors Q5 and Q7, the MOS transistor Q7 is not put into the ON state during a pre-charge period and drain current flows in substantially only the MOS transistor Q5.

In this case, the following equation is given:

W/L (Q4)=W/L (Q5)+W/L (Q6)>W/L (Q5)

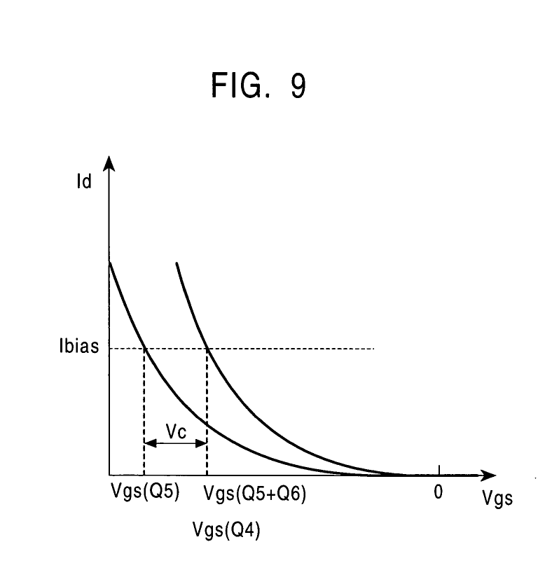

Thus, a voltage held by the input capacitor Cin2 is different, by Vc shown in FIG. 9, from a voltage in the circuit configuration having only the MOS transistor Q4. During a write period, the drains of the MOS transistors Q5 and Q6 are always in connected states. Thus, in the process of the output voltage OUT getting closer to Vdd, at a point where the output voltage OUT comes close to Vdd by Vc and where that bias current Ibias is equal, the writing is completed. Thus, appropriately setting the division ratio of W/L of the MOS transistors Q5 and the W/L of the MOS transistor Q6 can reduce the potential difference between the input voltage IN and the output voltage OUT, even when the input voltage IN is very close to Vdd.

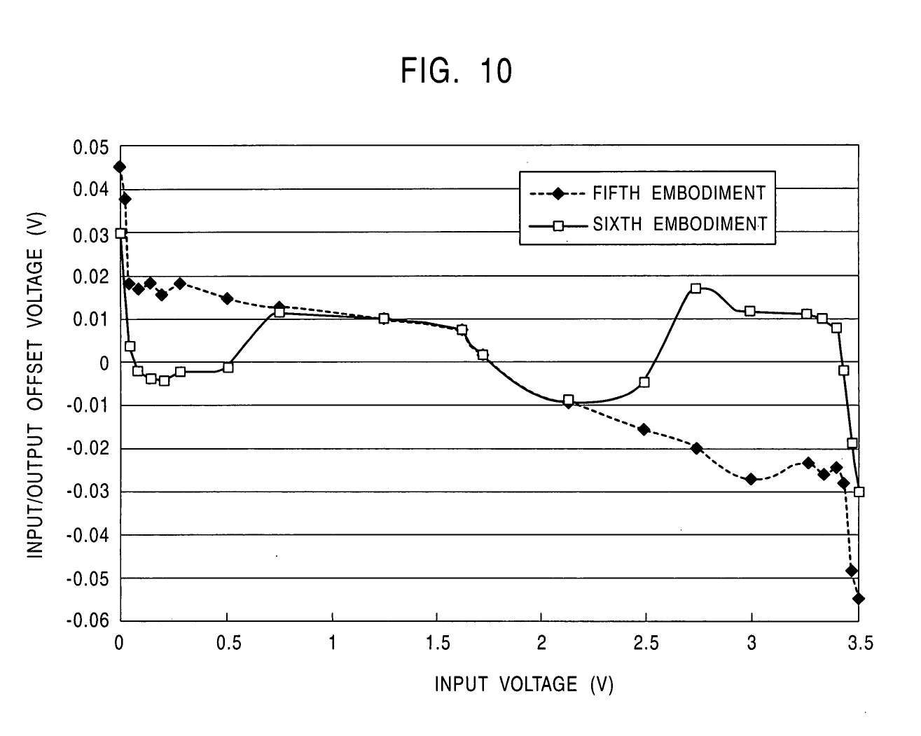

Even for the MOS transistor Q2 shown in FIG. 7, arranging a plurality of NMOS transistors in the same manner can reduce the potential difference between the input voltage IN that is very close to Vss and the output voltage OUT. FIG. 10 is a graph illustrating an effect according to the sixth embodiment in which the MOS transistor Q4 (or Q2) is configured as shown in FIG. 8B. As shown in FIG. 10, the range of change in an input/output offset voltage for the input voltage IN in the configuration shown in FIG. 8B is smaller than the range of change in an input/output offset voltage for the input voltage IN in the configuration shown in FIG. 7.

What is claimed is:

1. A source-follower circuit for driving a load at an input voltage for the circuit, comprising:
a metal-oxide semiconductor transistor;
capacitance means for storing a gate potential of the metal-oxide semiconductor transistor;
bias-current supplying means, which comprises a source-side current source and a drain-side current source, for supplying a bias current to the metal-oxide semiconductor transistor; and
control means for forcibly setting a source potential of the metal-oxide semiconductor transistor to the input voltage so that the metal-oxide semiconductor transistor's gate potential that is varied by the bias-current supplying means is stored by the capacitance means, and then, for applying the gate potential stored by the capacitance means to a gate of the metal-oxide semiconductor transistor so that the metal-oxide semiconductor transistor is operated and the source-side current source is operated, thereby driving the load at the input voltage.

2. A source-follower circuit according to claim 1, wherein the metal-oxide semiconductor transistor comprises an n-channel metal-oxide semiconductor transistor and a p-channel metal-oxide semiconductor transistor, and the control means selectively drives one of the n-channel metal-oxide semiconductor transistor and the p-channel metal-oxide semiconductor transistor in accordance with the value of the input voltage.

3. A source-follower circuit according to claim 1, wherein one end of the capacitance means is connected to ground or a constant potential.

4. A source-follower circuit for driving a load at an input voltage for the circuit, comprising:
a first metal-oxide semiconductor transistor;
first capacitance means for storing a gate potential of the first metal-oxide semiconductor transistor;
first bias-current supplying means, which comprises a source-side current source and a drain-side current source, for supplying bias current to the first metal-oxide semiconductor transistor;
a second metal-oxide semiconductor transistor;
second capacitance means for storing a gate potential of the second metal-oxide semiconductor transistor;
second bias-current supplying means, which comprises a drain-side current source, for supplying bias current to the second metal-oxide semiconductor transistor; and
control means for forcibly setting a source potential of the first metal-oxide semiconductor transistor to the input voltage so that the first metal-oxide semiconductor transistor's gate potential that is varied by the first bias-current supplying means is stored by the first capacitance means, for causing the second capacitance means to store a difference potential between a gate voltage of the second metal-oxide semiconductor transistor and the input voltage, the gate voltage of the second metal-oxide semiconductor transistor being generated by the second bias-current supplying means, and then, for applying the gate potential stored by the first capacitance means to a gate of the first metal-oxide semiconductor transistor so that the first metal-oxide semiconductor transistor is operated and applying the difference potential, stored by the second capacitance means, between an output terminal for the load and a gate of the second metal-oxide semiconductor transistor so that the second metal-oxide semiconductor transistor is operated, thereby driving the load at the input voltage.

5. A source-follower circuit according to claim 4, further comprising a first circuit having the first metal-oxide semiconductor transistor and the second metal-oxide semiconductor transistor, both thereof being n-channel metal-oxide semiconductor transistors, and a second circuit having the first metal-oxide semiconductor transistor and the second metal-oxide semiconductor transistor, both thereof being p-channel metal-oxide semiconductor transistors, wherein the control means selectively drives one of the first circuit and the second circuit in accordance with the value of the input voltage.

6. A source-follower circuit according to claim 4, further comprising resistance control means, wherein the second metal-oxide semiconductor transistor comprises third and fourth metal-oxide semiconductor transistors, sources and gates of the third and fourth metal-oxide semiconductor transistors being interconnected, and wherein the resistance control means controls an inter-drain resistor provided between drains of the third and fourth metal-oxide semiconductor transistors when a difference potential between a gate voltage of the third and fourth metal-oxide semiconductor transistors and the input voltage is stored by the second capacitance means and when the difference potential stored by the second capacitance means is applied between the output terminal for the load and the gates of the third and fourth metal-oxide semiconductor transistors.

7. A source-follower circuit according to claim 6, wherein the inter-drain resistor comprises fifth, sixth, and seventh metal-oxide semiconductor transistors, and the resistance control means controls each transistor to be turned on and off so that a resistance value is adjusted.

8. A drive device for a liquid-crystal display device, the liquid-crystal display device having a scan line and a data line which are connected so as to cross each other via a thin film transistor connected to a pixel electrode and the drive device having a data driver for supplying an analog signal to the data line, the data driver having a buffer circuit that comprises:
a metal-oxide semiconductor transistor;
capacitance means for storing a gate potential of the metal-oxide semiconductor transistor;
bias-current supplying means, which comprises a source-side current source and a drain-side current source, for supplying bias current to the metal-oxide semiconductor transistor; and
control means for forcibly setting a source potential of the metal-oxide semiconductor transistor to the input voltage so that the metal-oxide semiconductor transistor's gate potential that is varied by the bias-current supplying means is stored by the capacitance means, and then, for applying the gate potential stored by the capacitance means to a gate of the metal-oxide semiconductor transistor so that the metal-oxide semiconductor transistor is operated and the source-side current source is operated, thereby driving the load at the input voltage.

9. A drive device according to claim 8, wherein the metal-oxide semiconductor transistor comprises an n-channel metal-oxide semiconductor transistor and a p-channel metal-oxide semiconductor transistor, and the control means selectively drives one of the n-channel metal-oxide semiconductor transistor and the p-channel metal-oxide semiconductor transistor in accordance with the value of the input voltage.

10. A drive device according to claim 8, wherein one end of the capacitance means is connected to ground or a constant potential.

11. A drive device for a liquid-crystal display device, the liquid-crystal display device having a scan line and a data line which are connected so as to cross each other via a thin film transistor connected to a pixel electrode and the drive device having a data driver for supplying an analog signal to the data line, the data driver having a buffer circuit that comprises:
a first metal-oxide semiconductor transistor;
first capacitance means for storing a gate-source bias voltage of the first metal-oxide semiconductor transistor;
first bias-current supplying means, which comprises a source-side current source and a drain-side current source, for supplying bias current to the first metal-oxide semiconductor transistor;
a second metal-oxide semiconductor transistor;
second capacitance means for storing a gate potential of the second metal-oxide semiconductor transistor;
second bias-current supplying means, which comprises a drain-side current source, for supplying bias current to the second metal-oxide semiconductor transistor; and
control means for forcibly setting a source potential of the first metal-oxide semiconductor transistor to the input voltage so that a first metal-oxide semiconductor transistor's gate potential that is varied by the first bias-current supplying means is stored by the first capacitance means, for causing the second capacitance means to store a difference potential between a gate voltage of the second metal-oxide semiconductor transistor and the input voltage, the gate voltage of the second metal-oxide semiconductor transistor being generated by the second bias-current supplying means, and then, for applying the gate potential stored by the first capacitance means to a gate of the first metal-oxide semiconductor transistor so that the first metal-oxide semiconductor transistor is operated and applying the difference potential, stored by the second capacitance means, between an output terminal for the load and a gate of the second metal-oxide semiconductor transistor so that the second metal-oxide semiconductor transistor is operated, thereby driving the load at the input voltage.

12. A drive device according to claim 11, wherein the data driver further comprises a first circuit having the first metal-oxide semiconductor transistor and the second metal-oxide semiconductor transistor, both thereof being n-channel metal-oxide semiconductor transistors, and a second circuit having the first metal-oxide semiconductor transistor and the second metal-oxide semiconductor transistor, both thereof being p-channel metal-oxide semiconductor transistors, and wherein the control means selectively drives one of the first circuit and the second circuit in accordance with the value of the input voltage.

13. A drive device according to claim 11, further comprising resistance control means, wherein the second metal-oxide semiconductor transistor comprises third and fourth metal-oxide semiconductor transistors, sources and gates of the third and fourth metal-oxide semiconductor transistors being interconnected, and wherein the resistance control means controls a resistance value of an inter-drain resistor provided between drains of the third and fourth metal-oxide semiconductor transistors when a difference potential between a gate voltage of the third and fourth metal-oxide semiconductor transistors and the input voltage is stored by the second capacitance means and when the difference potential stored by the second capacitance means is applied between the output terminal for the load and the gates of the third and fourth metal-oxide semiconductor transistors.

14. A drive device according to claim 13, wherein the inter-drain resistor comprises fifth, sixth, and seventh metal-oxide semiconductor transistors, and the resistance control means controls each transistor to be turned on and off so that a resistance value is adjusted.
